(19) United States
(12) Patent Application Publication
(10) Pub. No.: US 2002/0026602 A1
(43) Pub. Date: Feb. 28, 2002

(54) System and method for identification of media by detection of error signature

(76) Inventor: Jamie Edelkind, Holl, MA (US)

Correspondence Address: Roberts Abokhair & Mardula, LLC, Suite 1000, 11800 Sunrise Valley Drive, Reston, VA, 20191-5302, US

(21) Appl. No.: 09/876,014

(22) Filed: Jun. 7, 2001

Related U.S. Application Data
(60) Provisional application No. 60/209,848, filed on Jun. 7, 2000.

(51) Int. Cl. H04L 1/22; H04B 1/74; H02H 3/05; H03K 19/003; H04N 7/64; H05K 10/00

(52) U.S. Cl. 714/6; 386/113; 369/53.1; 360/53

(57) ABSTRACT

A system and method for analyzing the errors inherent in the manufacture and recording of media and utilizing those errors as a signature for the specific media copy. Manufactured media, in this case CD's and similar type digitally encoded media, contain errors that are truly random in nature. Randomness is reflected in the spatial distribution of the E11 and E12 errors. These errors arise from a variety of sources and are manifested by experimental observation in non-correlative distribution. The nature of the errors that occur on parallel manufactured optical media can be classified into several categories: Recording errors, Encoding errors, Mastering errors, Molding defects, Materials defects, Contamination defects, Coating defects, Handling defects, Surface contamination, Playback errors, Optical ambiguity, A/D nonlinearity, and CODEC error. These errors all contribute to a unique error signature for each item of media manufactured. Using these unique signatures of errors, the individual identification of each piece of media can be established. Thus a method for the detection of a media copy signature is also established.

### RELATED APPLICATIONS

This application claims the benefit of the U.S. Provisional Application No. 60/209,848, filed Jun. 7, 2000, entitled “System and Method for the Identification of Media by Detection of Error Signature” and naming Jamie Edelkind as inventor.

### FIELD OF THE INVENTION

This invention relates generally to identification of media and copies thereof. More particularly the present invention is a system and method for analyzing the errors inherent in the manufacture and recording of media and utilizing those errors as a signature for the specific media copy.

### BACKGROUND OF THE INVENTION

A CD can store up to 74 minutes of music. Therefore the total amount of digital data that must be stored on a CD is:

44,100 sample s/channel/second*2 bytes/sample*2 channels*74 minutes*60 seconds/minute=783,216,000 bytes

To fit over 783 megabytes onto a disk only 12 centimeters in diameter means the individual bytes have to be physically fairly small. While this is accomplished in today's CD's the small physical size of bytes of data can lead to physical errors that are embodied on the CD.

A CD is a fairly simple piece of plastic about 1.2 millimeters thick. Most of the CD consists of an injection-molded piece of clear polycarbonate plastic. During manufacturing this plastic is impressed with microscopic bumps arranged as a single, continuous, extremely long spiral track of data. We will return to the bumps in a moment. Once the clear piece of polycarbonate is formed, a thin, reflective aluminum layer is sputtered onto the disk, covering the bumps. Next a thin acrylic layer is sprayed over the aluminum to protect it. The label is the printed onto the acrylic.

A CD has a single spiral track of data circling from the inside of the disk to the outside. The data track of a CD is approximately 0.5 microns wide, with 1.6 microns separating one track from the next. The track consists of a series of elongated bumps 0.5 microns wide, a minimum of 0.97 microns long and 125 nanometers high.

The small dimensions of the bumps makes the spiral track on a CD extremely long. To read something this small an incredibly precise disk-reading mechanism is needed.

The CD player has the job of finding and reading the data stored as bumps on the CD. Because the bumps are so small, the CD player is an exceptionally precise piece of equipment. The drive consists of 3 fundamental components:

A drive motor to spin the disk. This drive motor is precisely controlled to rotate between 200 and 500 RPMs depending on which track is currently being read.

A laser and a lens system to focus in on the bumps and read them

A tracking mechanism that can move the laser assembly so that the laser's beam can follow the spiral track. The tracking system has to be able to move the laser at micron resolutions.

Inside the CD player various processing algorithms form the data into understandable data blocks and send them either to the DAC (in the case of an audio CD) or to the computer (in the case of a CD-ROM drive).

The job of the CD player is to focus the laser on the track of bumps. The laser beam passes through the polycarbonate layer, reflects off the aluminum layer and returns to an opto-electronic device that detects changes in light. The bumps reflect light differently than the “lands” (the rest of the aluminum layer), and the opto-electronic sensor can detect that change in reflectivity. The electronics in the drive interpret the changes in reflectivity to read the bits that make up the bytes of information.

It is critical that the laser beam be centered on the data track. This centering is the job of the tracking system. The tracking system, as it plays the CD, has to continually move the laser outward. As the laser moves outward, the spindle motor slows the speed at which the CD is revolving so that the data coming off the disk maintains a constant rate.

However, a variety of conditions exist which must be dealt with and compensated for if reading data on a CD is to be accomplished.:

Because the laser is tracking the spiral of data using the bumps, there can not be extended gaps in the data track where there are no bumps. To solve this problem data is encoded using EFM (eight-fourteen modulation). 8-bit bytes are converted to 14 bits.

Because the laser wants to be able to move between songs, there needs to be data encoded within the music telling the drive “where it is” on the disk. This problem is solved using what is known as “subcode data”. Subcode data can encode the absolute and relative position of the laser in the track, and can also encode things like song titles.

Because the laser may misread a bump, there needs to be error correcting codes to handle single-bit errors. To solve this problem, extra data bits allow the drive to detect single-bit errors and correct them.

Because a scratch or speck on the CD might cause a whole packet of bytes to be misread (known as a burst error), the drive needs to be able to recover from such an event. This problem is solved by actually interleaving the data on the disk, so that it is stored non-sequentially around one circuit of the disk. The drive actually reads data one revolution at a time and un-interleaves the data to play it.

If a few bytes are misread in music, then the worst that can happen is a little fuzz during playback. When data is stored on a CD, however, any data error is catastrophic. Therefore additional error correction codes are used when storing data on a CD-ROM.

All manufactured media, including CD's, Memory Chips, and other media. encoded with digital data whether recorded through serial or parallel data placement, contains stochastically distributed imperfections. This random noise does not interfere in digital fidelity since special error correction codes exist to remove the digital manifestations of the errors and the digitizing process eliminates most others. While these errors are undesirable noise from the perspective of the digital data user, it is possible to use this very noise as the source of a high quality digital fingerprint or signature of the media, tracing back its exact lineage as well as defining its iterative genesis. Of all the copies reproduced this precise copy is not digitally equal to any other so long as there has not been any error correction applied during the intervening steps.

This digitally manifested fingerprint concept applies to any form of digital storage or transmission, including but not limited to, digital compact disks, digital versatile disks, digital tape, hard disks, floppies, or even to digital transmission media such as radio, or fiber optics, or even to more esoteric digital storage systems such as ROM, EPROM or RAM. The only criteria that is necessary is that the media and playback mode encompass a digital error correction scheme for which an activity algorithm or process may be monitored.

### SUMMARY OF THE INVENTION

Typically error correction codes call for the data to be distributed in noncontiguous locations thus preventing the low-level errors from interfering in digital modalities. In media where such imperfections are manifested through the recordation and playback, it is possible to establish a pattern for such distribution of errors as may exist. This pattern has correlative and non-correlative associations. By understanding the nature of the correlation's that may result from the data accumulation in the media it is relatively straightforward to decode a Nyquist dependant unique signature independent of the Cross Interleave Reed-Solomon code (CIRC) or other error correction scheme.

A digital signature derived according to an extracted independent image map and time code is in most cases non-reproducible. This remains true even when the signature is composed of a statistical distribution of information that is both spatially and temporally dependent upon the playback device decoder or reader. This may be managed by repeatedly referencing the error distribution to the declared and encoded data through and by algorithmic process it is straightforward to generate a range of deviated images. A repeatedly derived virtual multidimensional signature is in fact an image that bears a deviated compliance one to the other. The envelope of the signature is large enough to provide landmarks un-obscured by shot, and burst noise or physical damage (to a limited extent) yet unique enough to provide for all real-world discrimination. With a sufficiently large number of landmarks spatially distributed throughout the signature, a standardized milieu can provide for all foreseeable applications.

A requirement on any practical fingerprint is that it be representable in bounded size and that it have an established representation. This of course provides an absolute upper limit to the extent, flexibility and utility of the signature and thus an absolute boundary. This boundary condition is a theoretical impediment only in the most miniscule system of data. As the size of the data structure expands, the unique signatures available expands in geometric abstraction. It is important to note that the content is unimportant insofar as the extracted signature. It is merely enough that the structure of the physical media exists whether full or devoid of content. Special applications may require that the content be hashed together with the media signature in order to provide an inalterable cyclic notary. Such utility is use dependant and may be applied as needed. This limitation is an issue only where the signature size must be represented in a trivial number of bits. Real systems will have high quality fingerprints expressible with a few hundreds to thousands of bits.

### DETAILED DESCRIPTION OF THE INVENTION

While the invention herein described above is portable to many different media, as discussed earlier a specific embodiment in terms of the most common manufactured format can provide great benefit in teaching the art of this invention. The most ubiquitous digital media in distribution today is the audio compact disc, and is the initial implementation target for a signature of the present invention.

A CD can store up to 74 minutes of music, so the total amount of digital data that must be stored on a CD is:

44,100 samples/channel/second*2 bytes/sample*2 channels*74 minutes*60 seconds/minute=783,216,000 bytes

To fit over 783 megabytes onto a disk only 12 centimeters in diameter means the individual bytes have to be physically fairly small. By looking at the physical construction of the CD you can learn how small they are.

A CD is a fairly simple piece of plastic about 1.2 millimeters thick. Most of the CD consists of an injection-molded piece of clear polycarbonate plastic. During manufacturing this plastic is impressed with microscopic bumps arranged as a single, continuous, extremely long spiral track of data. Once the clear piece of polycarbonate is formed, a thin, reflective aluminum layer is sputtered onto the disk, covering the bumps. Then a thin acrylic layer is sprayed over the aluminum to protect it. Then the label is printed onto the acrylic.

A CD has a single spiral track of data circling from the inside of the disk to the outside. The track is approximately 0.5 microns wide, with 1.6 microns separating one track from the next. The track consists of a series of elongated bumps 0.5 microns wide, a minimum of 0.97 microns long and 125 nanometers high.

The CD player finds and reads the data stored as bumps on the CD. Because the bumps are so small, the CD player is an exceptionally precise piece of equipment. The drive consists of 3 fundamental components:

A drive motor to spin the disk. This drive motor is precisely controlled to rotate between 200 and 500 RPMs depending on which track is currently being read.

A laser and a lens system to focus in on the bumps and read them

A tracking mechanism that can move the laser assembly so that the laser's beam can follow the spiral track. The tracking system has to be able to move the laser at micron resolutions.

The CD player focuses the laser on the track of bumps. The laser beam passes through the polycarbonate layer, reflects off the aluminum layer and returns to an optoelectronic device that detects changes in light. The bumps reflect light differently than the “lands” (the rest of the aluminum layer), and the opto-electronic sensor can detect that change in reflectivity.

Because the laser may misread a bump, there needs to be error-correcting codes to handle single-bit errors. To solve this problem, extra data bits allow the drive to detect single-bit errors and correct them.

Because a scratch or speck on the CD might cause a whole packet of bytes to be misread (known as a burst error), the drive needs to be able to recover from such an event. Actually actually interleaving the data on the disk solves this problem, so that it is stored non-sequentially around one circuit of the disk. The drive actually reads data one revolution at a time and un-interleaves the data to play it.

If a few bytes are misread in music, then the worst that can happen is a little fuzz during playback. When data is stored on a CD, however, any data error is catastrophic. Therefore additional error correction codes are used when storing data on a CD-ROM.

Audio disc is ubiquitous because of its suitability for mass production in terms of robustness, portability, speed and cost. Typical of today's manufacturing is a parallel production plant in which 680 through 19000 megabytes can be encoded on the media in the space of a second or two. Compared to the highest data rate from serial recording or playback this is immensely superior. Further, this data is now permanent, secure, and transportable and subject to durability standards that enhance its' utility. However, the very robustness of the media is largely based in the application of error correction to tolerate relatively huge error rates. While it is true that most of the content placed on CD style media is digital, the encoding scheme is certainly fully rooted in the analog real world. Play back device make extensive use of technology to extract a signal that lends itself to decoding and digitizing.

The errors accumulated through manufacturing and playback typically resolve themselves by error correction codes and data redundancy schemes. On a typical audio CD fully 25% of the data is present merely to provide error correction. Even in lossy systems such as Video DVD extreme lossiness is the trade off for resolved digital. In DVD think best case of 75% loss. In a play back venue, where digital perfection is not an overriding concern, the loss of information is less important than the improvement of the signal to noise ratio. In CD ROM and DVD ROM such a cavalier approach would not work. In such and similar applications a zero signal to noise ratio is required. Procuring such performance extracts a significant overhead and penalty in the ever-present error correction code.

The first assumption that we can make is that manufactured media, in this case CD's and similar type digitally encoded media, contain errors that are truly random in nature. Randomness in this case is limited to the spatial distribution of the E11 and E12 errors. These errors arise from a variety of sources and are manifested by experimental observation in non-correlative distribution. Statistically, certain bias correlations exist particular to types of manufacturing protocols, but in resolving individual error at the graininess of the digital footprint there exists no discemable manifest correlation between individual errors. However, in a particular manufacturing run this correlative signature can determine the level of graininess necessary to suggest conformity and identity to a manufacturing source.

Although in some sense any disc that plays without uncorrectable errors is “perfect,” there are other considerations. For one thing, we may wish to know how close is it to getting uncorrectable errors. Obviously, a disc with very low error rates has more tolerance for dirt, scratches, and the differences of players before it will produce an uncorrectable error. Other discs, although they may not produce uncorrectable errors, may be on the verge of doing so. In addition, older first generation players may produce many uncorrectable errors on such a disc because they use a less effective error correction algorithm than newer player do. Because the time code used to search to a location does not have CIRC error correction, CD-ROM access times can rise dramatically with error rates, even though the data is fully recoverable.

A CD could not work without a highly effective error detection and correction Scheme. Because the pits on the CD are so small, it is impossible to read the disc without errors. Keep in mind that the width of the pits is less than the wavelength of light used to reads them. Therefore, it is the error detection and correction codes that really make the CD feasible. The error detection and correction code used on CD's is known as Cross Interleave Reed-Solomon Code (CIRC).

This scheme uses two principles to achieve a remarkable ability to detect and correct errors. The first is redundancy. This means that extra data is added, which gives you an extra chance to read it. For instance, if all data were recorded twice, you would have twice as good a chance of recovering the correct data. The CIRC has a redundancy of about 25%; that is, it adds about 25% additional data. This extra data is cleverly used to record information about the original data, which allows for the ability to deduce what the missing information must have been.

The other principle used is interleaving. This means that the data is distributed over a relatively large physical area. If the data were recorded sequentially, a small defect could easily wipe out an entire word. With CIRC, the bits are interleaved before recording, and de-interleaved on playback. What happens is that the bits of individual words are mixed up and distributed over many words. Now, to completely obliterate a single byte, you have to wipe out many bytes. Using this scheme, local defects destroy only small parts of many words. In most cases there is enough left of each sample to reconstruct it. To completely wipe out a data block would require a hole in the disc of about 2 mm in diameter.

The CIRC error correction used in CD Players uses two stages of error correction called C1 and C2, with de-interleaving of the data between the stages. The error correction chip in the CODEC of “Red-Book” compliant players uses the “Super-strategy’ algorithm that can correct two bad symbols per block in the first stage and two bad symbols per block in the second stage.

Therefore, the error type E11 means one bad symbol was corrected in the C1 stage. E21 means two bad symbols were corrected in the C1 stage. E31 means that there were three or more bad symbols at the C1 stage. This block is uncorrectable at the C1 stage, and is passed to the C2 stage. Because of the de-interleaving of the data between the stages, those three (or more) bad symbols are now in separate blocks, and so can be corrected by the C2 stage.

E12 means one bad symbol was corrected in the C2 stage and E22 means two bad symbols were corrected in the C2 Stage. E32 means that there were three or more bad symbols in one block at the C2 stage, and therefore this error is not correctable.

BLER (Block Error Rate) is defined as the number of data blocks per second that contain detectable errors, at the input of the C1 decoder. This is the most general measurement of the quality of a disc. The “Red Book” specification IEC908) calls for a maximum BLER of 22 per second averaged over ten seconds. Discs with higher BLER are likely to produce uncorrectable errors. Nowadays, the best discs have average BLER below 10. A low BLER shows that the system as a whole is performing well, and the pit geometry is good.

However, BLER only tells you how many errors were generated per second, it doesn't tell you anything about the severity of those errors. Therefore, it is important to look at all the different types of errors generated. Just because a disc has a low BLER, doesn't mean the disc is good. For instance, it is quite possible for a disc to have a low BLER, but have many uncorrectable errors due to local defects. The smaller errors that are correctable in the C1 decoder are considered random errors. Larger errors like E22 and E32 are considered burst errors and are generally caused by local defects. The sequence E11, E21, E31, E12, E22, E32 represents errors of increasing severity.

A dropout is defined as an instance where the signal coming off the disc drops below 75% of its nominal value. Pinholes, black spots, or large scratches are typically the cause of these defects, and can produce burst errors. There is no standard definition of a dropout for CD's, only of its consequences. For instance, if a large burst error (E22 or E32) occurs at a particular spot on the disc, and there are also dropouts at that same place, then the error is due to a gross physical defect. On the other hand, if there are many burst errors and no dropouts, the problems may be poor pit geometry.

Track loss occurs when the signal from the pickup is insufficient to discriminate and provides anomalous input to the servo tracking mechanism. This generally indicates track skipping. Since track skipping is not allowed by the Red Book specification any track loss is clearly a condition that presents itself post manufacturing due to standardized rejection control in the Q/A of all manufacturers. In order to work properly, the pits on the disc must have a certain size and shape. There are specifications for pit length, depth, and width, but one would need an AFM (Atomic Force Microscope) to measure them.

Disc performance can only be measured by playing the disc. Unfortunately it is only in the playback that one can deduce anything of a digital nature about the disc. As a result, it is quite possible for discs that meet specifications to have problems playing on certain players. Similarly, discs that may be substantially out of spec, may work fine on other players.

Errors on a disc are not solely a “physical” thing. It is a manifestation of how well the total system (disc+player) is working. The disc itself does not have an error rate; playing the disc produces errors, some repeatable and some random. However, certain errors that are produced in the encoding are uniform and strictly repeatable. This presents us clear markers that are unique to the encoding event for a particular encoding. Other uniform errors are mastering and molding errors that also present repeatable distributions of errors.

The world of digital media is clearly a complex system of standardization that has evolved to solve the distribution criteria for digital systems. It is through this standardization and complexity that certain solutions present themselves for zeroing in on the identity crisis for media. The ability to reproduce a stochastic result from a defined environment is unique to digital encoding topologies. Where the landmarks etched into a static media are definable in digital form but not repeatable from a manufacturing perspective it is possible to find an additive identity set that is protocol compliant and content derivative.

A signature that provides a unique and testable identity must be large enough to account for all possible serializations in the universe of the media. In Media terms the universe for a particular CD title would never in practical terms exceed 100 million. A title is defined as a particular encoding sequence on a Glass master. This is distinguished from a license title, which is an abstract, content-based matter related solely to the information and not the implementation of the content with media. In the history of media distribution and manufacturing the largest single pressing of a title approximated 1 million. Allowing for multiple pressings and purposeful stamper recycling the largest accommodated set of title identity could not exceed the 100 million mark. By comparing content with index and time marks it is relatively easy to identify a media to a specific lot and manufacturer. This is done with precision since it is impossible to produce a Glass master to conformity at the bit level resolution. In fact, even under the best conditions a Laser Beam Recorder (LBR) working from the identical encoding data would require no less than 350 million attempts to be reasonably certain of having two glass masters that were digitally identical in raw non CIRC terms.

Should two separate LBR's attempt to produce digitally identical Masters the statistical certainty to produce two identical masters increases to an amazing 7.682×10³⁶ attempts. Since a typical time interval for an LBR to record and process a Master is on the order of 1 hour. The universe should cease to exist before such a certainty comes to pass. Barring an amazing and unpredicted advance in the ability of manufacturing technology the surety of uniqueness for the Masters is predicate.

The nature of the errors that occur on parallel manufactured optical media can be classified into several categories:

1. Recording errors

2. Encoding errors

3. Mastering errors

4. Molding defects

5. Materials defects

6. Contamination defects

7. Coating defects

8. Handling defects

9. Surface contamination

10. Playback errors

11. Optical ambiguity

12. A/D nonlinearity

13. CODEC error

While not by any means an exhaustive list, it certainly bears directly on the morbidity rate of media. Notwithstanding this lengthy list the functionality of optical media in the form of the CD and DVD is without question.

Before embarking on a definition of a fingerprint resolution algorithm it is vital to understand the nature and character of the errors that are utilized in the present invention.

The parameters and the utility are as follows:

1. The errors must be independent of the content

1.1. Certainly, the errors, without impact on the utility of the present invention, may be a result and consequence of the content, but the distribution is random. A correlation between the digital errors and the content, if it existed, could bias the signature so that the actual available signatures would in fact be much moderated. The consequence thereupon would be a much greater likelihood of non-unique signatures. Experimental results and accepted art show that in fact the errors are independent of the content.

2. The errors must be permanent

2.1. The predicate utility of the present invention lies in its' ability to establish a natural way of deriving identity for otherwise non-distinguishable media. Should the errors be transitory any derived signature would be volatile and of little value from a standpoint of licensure or identity tracking.

2.2. Since the present invention uses pattern matching to determine the compliance to a protocol signature, it will tolerate certain deviations in individual errors. Certain errors while permanent in the media may resolve themselves in different fashions on different players. Therefore, the transitory nature of borderline defects is non-fatal to the signature algorithm, provided that overall the signature signal can emerge from the remaining error map.

3. The errors must not be resolvable digitally

3.1. To prevent counterfeiting the, signature of the present invention must be a consequence of the manufacturing, and not a product of the content. If it were possible to resolve the errors in a deliberate fashion it would present a point of attack.

3.2. In order to provide uniqueness the errors must not be encodeable through the recording process. In fact this is so. Even if were possible to map the entire error map and content, it is a bar that the encoding of the content and the distribution of the errors are unrelated.

4. The errors must be stochastic and randomly distributed

4.1. The present invention is a deterministic algorithmic process and as such its output is dependant upon its input as well as a protocol. In order that the signatures have a high quality of uniqueness as well as testability it is a critical issue that the digital errors be of a true non-correlative nature. Not only are the locations important but also the identity of the errors.

4.2. A signature not only requires uniqueness it also needs to be readily extractable. The nature of the errors combine a stochastic coverage with random distribution to a high degree of uniformity on an average density but with a near zero correlation between the spatial and temporal location of the errors.

5. The errors must have a period of distribution to provide a large signature dynamic

5.1. Extraction of the signature is in part dependant on the accessibility of the digital errors. If the period of the errors otherwise acceptable is too lengthy, acquisition time for the signature may present an unbearable overhead.

5.2. The consequence of a too lengthy period is that the protocol for the signature would have insufficient data to create a statistically comfortable unique signature.

5.3. The consequence of a too short period is that the noise component of the pattern algorithm may overwhelm the pattern-matching algorithm providing spurious output.

6. The errors must be resolvable on any compliant playback device or reader

6.1. Signatures must be transportable to any standardized player, or special hardware would be needed. This would present a potentially insurmountable bar to application of the technology.

6.2. Partial adoption of the standard would mitigate the value. The present invention process is readily implementable because it makes use of standardization and does not seek to impose an additional functional barrier.

7. The errors must be so intermingled with the content to prevent counterfeiting

7.1. A signature must contained mathematical hashes to co-mingle declared data with consequential manufacturing artifacts. The separation of the two would provide easy access for counterfeiters.

7.2. Since a matching matrix database would be generated from the signature, simple pattern matching could present a prodigious processing challenge. Having known content allows for a very definable indexing milieu.

These seven characteristics are required. Fortunately, such digital errors are readily available. The CODEC standardized for all compatible media defines certain correctable error conditions. This non-fatal, to data, error is called E11 or a level one error. Primarily, coating and encoding non-uniformities cause this error. Since the source of these errors are truly random and distributed in a relatively continuous ratio across the plane of the media and of course are ubiquitous to all manufactured media they make an ideal source of signature generation.

Application of Technology

Content providers whether commercial or private typically have a proprietary interest in the data that they record for distribution. This interest manifests itself in a financial, artistic and legal sense. Not only do they want to insure that their content is delivered to the correct user, but they further want to insure that their content maintains a certain degree of fidelity. Strict rules govern the release, use and distribution of this content. The present invention provides an efficient and ubiquitous paradigm that is backwards compatible and directly applicable and implementable.

One embodiment of this invention would be in the form of a software code that would monitor the CODEC output of conventional CD and DVD ROM devices.

Acquiring the time code of the E11 activity as well as the data that envelopes the CODEC flag by a protocol level will map a distributed image of the present invention for a particular disk. The acquisition would then be rendered into mapped memory in a manner that correlates the spatial distribution on the Disk to that of the memory register sequencing. At this step in the process, suitable algorithms will interleave the memory cells into a standardized signature protocol.

Production runs of a specific “Title” are limited by the “up” time of the manufacturing equipment and the deterioration of the masters and molds. Theoretical maximums (never done, but believed possible) could yield between 1 and 3 million disks. In order for a serialization based on a signature of the present invention to be of fine utility it must provide for many orders of magnitude greater identification. Further, the present invention must, in addition, provide an absolute identity enhancement to the signature such that all identifying characteristics are provided for. In the protocol based the present invention the disk information is declared while the signature image is framed and formatted into 128 separate octets, the present invention will yield a unique stochastic signature 128 bytes long and a title signature also of equal length.

In interpreting the signature of the present invention the octal signature for each frame becomes a key component of the overall signature of the present invention. However, in the individual frame the library signature is form fitted to a best match pattern. An iterative association algorithm of this type is similar to that utilized in OCR (optical character recognition. Any failure on a per frame basis may present an obscured signature.

Mathematically in order to guarantee uniqueness several criteria are required:

1. An associative title base large enough to prevent repetitive notations.

2. A landmark based signature that contains a significant stochastic distribution so as to prevent any correlation between media error distribution and the encoded content.

3. A large enough sampling of the framed non-decoded data that will contain terminal identifying characteristics.

The datum taken into account is:

a. All titles have declared codes and numbering schemes rendering them unique.

b. The certifying database can observe correspondent data and encoding marks to guarantee the identity of the title.

c. The maximum number of duplicate titles is less than the 10 billion.

d. The distribution of the errors observed by this embodiment is truly stochastic.

It is well known that uniqueness is not a requisite of randomness. However, it is simple to understand the causal relationship between randomness and uniqueness. Consider a dice with 6 sides. In any one throw we are certain that our result is both unique and random. However, with each subsequent throw our randomness remains the same but the likelihood of uniqueness drops. After two such throws the likelihood of uniqueness is less than even. In four such throws the likelihood of uniqueness becomes vanishingly small. After six throws uniqueness vanishes altogether.

Now, it is possible to chart a probability index for uniqueness. This is the same type of exercise that is undertaken by lotteries where the participant selects a sequence of numbers to win. However, insuring uniqueness is another matter altogether. In the real world this becomes a heuristic exercise of infinite length. In prose we say, “It is impossible to prove a negative.” However, in math, certain assumptions may give us a way to be certain for an integer set that uniqueness is present.

Having established an understanding of the underlying issue in the algorithm it is necessary that the next area of consideration is that of the reproduction of the media itself. The replication technology currently available introduces randomized digital errors in a predictable distribution and intensity in the portion of the manufacture called vapor metalization. This step takes the encoded media and coats it for playback via sputtering technology. Because of the nature of the features and the size of the media surface it is impossible to present a uniform flux. This in addition to the variations of the pit geometry contributes a fully random level of coating discrepancies to the surface. Having dealt with the unique protocol of the title itself, it is possible to look directly to the distributed E11 and E21 errors to identify the difference in the individual media's. As with fingerprints, the challenge is to establish a protocol that allows for unique landmarks as well as a manageable process for extracting a signature. Without reading and hashing every bit on the media it is impossible to establish a guaranteed unique fingerprint beyond all possibilities. However, given the constraints of individual titleage we can reduce the certainty of duplicate signatures, whether intentional or accidental to one in 1.844×10¹⁹ licenses.

This is a protocol issue based on a component signature adduced from the pattern distribution of CIRC level one correctable errors. Using a library conformed algorithm run against the first 64 seconds (single speed extracted time) and accumulating a 64 frame reference standard, a standard OCR pattern match algorithm set off against a library of 8 defined patterns is run against the mapped cell frames. This allows a protocol signature that when combined with the title signature is a unique signature within all practical real world constraints.

The signature acquisition is, like the data, redundant in the extreme. The pattern is based on the time code location of the Level one errors, best fit to a simple linear definition object. Yielding a two-dimensional pattern it is quick to process and repeatable. The resultant signature is above the Nyquist encoding limit. Acquiring the simple overall error system without conforming it to a library would prevent repeatable acquisition and could easily result in obscured signatures on varied playback players.

Hardware for acquisition of the signature already has a universal installed base. CD-ROM players incorporate outputs that allow software to register the activity of the CODEC. This activity flag in conjunction with the extracted clock information yields a Cartesian map of the Level one errors. Simply mapping the raw flag information into the memory cross-indexed against the extracted time code gives a raw digital output. Running conventional OCR algorithms against the grid map of the Memory gives a serial signature that is independent of the noise and higher burst errors of the media.

This scheme insures that the distributed natural digital signature of the present invention that is could not be obscured or falsified.

There are still certain practical consideration of implementing the present invention that require addressing. A CD ROM player comprises a buffer of RAM of varying size. The audio signal is played from the RAM during the course of playback of the CD ROM contents. This RAM can range anywhere from 100K to around 2 megabytes of RAM. In general, during the course of normal playback, the CD player will constantly retrieve audio data and keep the RAM buffer relatively full. As audio is played out for the listener, the digital signals are downloaded from the RAM buffer and reproduced in audio fashion for the listener. In this way, there is a constant flow of audio data coming from the buffer, while the buffer is somewhat more sporadically filled by digital data from the CD ROM that is retrieved. Use of the buffer therefore avoids the “stop start” nature of digital data that is retrieved from the CD ROM.

However, in order for the present invention to associate errors in signal with the physical location on the CD ROM itself, there must be more of a precise association of the signal being retrieved from the CD ROM and the physical location on the CD ROM from which the signal is being retrieved. Thus the present invention, in order to combat the “stop-start” of signal being placed into the buffer, loads the buffer to a high degree. The information that is loaded into the buffer is not played out but serves to decrease the overall capacity of the buffer so that signal that is played out as a digital signal is closely associated, in time, with the actual position of the read optics of the CD ROM player. Thus, there is relatively little delay between the notation of the physical position of the reader head and the actual signal that is coming from the CD ROM. Thus, any errors that are detected in the output signal can be directly associated with the physical location on the CD ROM.

While the CD ROM is playing, the CD ROM player performs “mode sensing.” Mode sensing comprises sensing information from the read optics concerning what is actually occurring with signal retrieved from the CD ROM. Associating the appropriate error with the mode that is sensed at the time the error has occurred is critical to establishing the random error signature of the CD ROM.

In the preferred embodiment of the present invention, the buffer is filled to approximately 90% so that mode sensing occurs within a brief period of time from when the error signal is detected. Thus, the physical location of the error can be determined within a resolution of approximately one frame (comprising 588 bits).

Thus, the mode sensing notes that an error is present at a particular location on the disk, and the sensing of the error signal determines what that error signal is at the location.

Since the present invention needs to detect errors that are present on the CD ROM, the system must be certain of what errors are actually being detected. For example, errors can occur as a result of the actions of the drive itself and errors can occur as a result of the media that is being sensed (the CD ROM). Since it is the media errors that the present invention seeks to detect, drive errors, if any, must be accounted for.

The present invention solves the problem of sorting drive errors from media errors by reading a physical area of the CD ROM more than once. The read optics of the CD ROM drive move to a location to be read, and a signal is read from that area. That specific area of the CD ROM is the re-read to determine if the signal from the first reading is different from the signal of the second reading. If the signals are the same, then it is certain, within a reasonable degree of error, that the error has occurred on the CD ROM. If however, the error changes upon re-reading, then there is most likely an error in the drive and that particular error signal from the CD ROM location will be discarded.

In the present invention all errors on a CD ROM are subject to re-reading in order to verify whether there is a media error present or if the error is a result of the CD ROM drive operations.

A system and method for the detection of a media copy signature has now been illustrated. It will be appreciated by those skilled in the art that this technique can be used to identify all manner of media from CD ROM's to individual microchips and processors thus providing positive identification of the individual media in question. Other applications will be apparent to those skilled in the art without departing from the scope of the invention as disclosed.

I claim:

1. A system for identification of individual media comprising:
An error correction means for monitoring digital media on which data is recorded A recording means connected to the error correction means for recording the errors caused by uncontrollable manufacturing artifacts;
A database means for receiving and storing the record of error correction;
A comparison means for comparing the stored recording of the error correction to subsequent error correction record to determine if the records are the same.

2. The system of claim 1 wherein the errors recorded comprise patterns of errors.

3. The system for identification of individual media of claim 2 wherein the patterns of errors are recorded for predetermined physical location of the digital media.

4. The system for identification of individual media of claim of claim 3 wherein the media are CD ROMs.

5. The system for identification of individual media of claim 3 wherein the media are DVDs.

6. The system for identification of individual media of claim 3 wherein the media are storage chips.

7. The system for identification of individual media of claim 3 wherein the patterns of errors are extracted into a library of symbols.

8. The system for identification of individual media of claim 7 wherein the symbols of the library are repeatable.

9. The system for identification of individual media of claim 3 further comprising a processor comprising instructions for creating a hash of the patterns of errors from the predetermined physical locations and from an error level signal combined with the content from the predetermined physical locations thereby identifying the media with unique specificity.

10. A method for uniquely identifying individual media comprising:
monitoring an error correction protocol applied to the playback of a particular media;
recording the error correction protocol;
storing the error correction protocol;
comparing a subsequent error correction protocol to the stored error correction protocol to determine if the two records are the same.

11. The method for uniquely identifying individual media of claim 10 wherein the error correction protocol describes patterns of errors and wherein the patterns of errors are stored.

12. The method for uniquely identifying individual media of claim 11 wherein the recording of the error correction protocol further comprises recording the error correction protocol for specific physical areas of the media.

13. The method for uniquely identifying individual media of claim 12 further comprising extracting the error correction protocol into a library of symbols.

14. The method for uniquely identifying individual media of claim 13 wherein the symbols in the library are repeatable.

15. The method for uniquely identifying individual media of claim 11 wherein the media are DVDs.

16. The method for uniquely identifying individual media of claim 11 wherein the media are CD ROMs.

17. The method for uniquely identifying individual media of claim 111 wherein the media are memory chips.

18. The method for uniquely identifying individual media of claim 11 further comprising creating a hash of the patterns of errors from the predetermined physical locations and from an error level signal combined with the content from the predetermined physical locations thereby identifying the media with unique specificity.
